(19) United States
(12) Patent Application Publication
(10) Pub. No.: US 2015/0040970 A1
(43) Pub. Date: Feb. 12, 2015

(54) Vacuum Deposition System For Solar Cell Production And Method Of Manufacturing

(71) Applicant: First Solar, Inc., Perrysburg, OH (US)

(72) Inventors: Raffi Garabedian, Los Altos, CA (US); Roger Malik, Warren, NJ (US); Jeremy Theil, Mountain View, CA (US); Jigish Trivedi, Perrysburg, OH (US); Ming Yu, Fremont, CA (US)

(73) Assignee: First Solar, Inc., Perrysburg, OH (US)

(21) Appl. No.: 14/452,306

(22) Filed: Aug. 5, 2014

Related U.S. Application Data
(60) Provisional application No. 61/862,827, filed on Aug. 6, 2013.
(60) Provisional application No. 61/871,151, filed on Aug. 28, 2013.

(51) Int. Cl. H01L 31/0304; C23C 16/22; H01L 21/64; H01L 31/18

(52) U.S. Cl. CPC H01L 31/0304; H01L 31/184; H01L 31/03046; C23C 16/22; H01L 31/18; H01L 21/64; H01L 2221/67
USPC 136/252; 438/94; 118/719

(57) ABSTRACT

An inline vacuum deposition system contains thermal source pairs configured in adjacent deposition zones. Dopant sources allow the electrical characteristics of the sequentially formed layers to be controlled for a preferred deposition growth profile.

This application claims priority to provisional application 61/862,827 filed Aug. 6, 2013 and to provisional application 61/871,151 filed Aug. 28, 2013.

### FIELD OF THE INVENTION

Disclosed embodiments relate generally to manufacturing a photovoltaic (PV) device with vacuum deposition, and more specifically, to high throughput manufacturing equipment and methods for manufacturing high efficiency PV devices.

### BACKGROUND OF THE INVENTION

A PV device generates electrical power by converting photo-radiation or light into direct current electricity using semiconductor materials that exhibit the PV effect. The PV effect generates electrical power upon exposure to light as photons, packets of light energy, are absorbed within the semiconductor to excite electrons that are thus able to conduct and move freely within the material.

A basic unit of PV device, commonly called a cell, may generate only small scale electrical power. Multiple cells may be electrically connected to aggregate the total power generated among the multiple cells within a larger integrated device, called a module. A PV module may include several PV cells, electrical conductors connecting the cells, additional front or back protective layers and encapsulant materials to protect the PV cells from environmental factors.

To generate electric power from light, the active area of a photovoltaic device generally includes a stack of semiconductor material layers modified through doping to have either an excess of electrons (becoming an n-type semiconductor) or a deficiency of electrons (becoming a p-type semiconductor). Placing differently conducting materials in contact creates a junction allowing a flow of electricity resulting from the freed electron charge potential. Front and back contacts connected to the semiconductor stack provide pathways through which the charge potential can flow to become an electrical current. Electrons can flow back to the junction through an external current path, or circuit.

Photovoltaic device manufacturing has included high-cost batch deposition formation of the functional semiconductor layers. For example, epitaxial grown Gallium Arsenide (GaAs) solar cells have demonstrated high single junction and multi-junction cell efficiencies compared to other solar absorber materials. However, using standard GaAs substrate material or Germanium substrates as a growth template are expensive when compared to standard Silicon single-crystal or polycrystalline solar cells on a cost per watt basis. Conventional epitaxial growth of GaAs by Metal Organic Chemical Vapor Deposition (MOCVD) uses costly gaseous precursors, such as Trimethyl Gallium (TMG) and Arsine (AsH3), in a batch growth process with growth on a round multi-wafer platen having poor wafer area packing density. Molecular Beam Epitaxy (MBE) has been also used to deposit high efficiency, multi-junction GaAs solar cells. However, MBE also suffers from a poor form factor multi-wafer platens and uses slow growth rates, thus making it also uncompetitive with Silicon solar cell technology. Known production methods have high costs and low throughput making them uncompetitive with standard Silicon solar cells which have lower conversion efficiency but which are less expensive to produce.

Therefore, it is desirable to provide an improved-throughput lower-cost method to deposit single-crystal GaAs epitaxial layers for manufacturing high efficiency solar cells.

### BRIEF DESCRIPTION OF THE DRAWINGS

The above, as well as other advantages of the present invention, will become readily apparent to those skilled in the art from the following detailed description of the disclosed embodiments when considered in the light of the accompanying drawings in which:

FIG. 1 depicts a block diagram of an inline vacuum deposition system.

FIG. 2 depicts a plan view of the inline vacuum deposition system.

FIG. 3 depicts a cross-section side schematic view of the inline vacuum deposition system along a central axis.

FIG. 4 depicts a cross-section side schematic view of a linear source taken along a central axis.

FIG. 5 depicts a top down schematic view of the linear source.

FIG. 6 depicts a cross-section side schematic view of a reservoir source taken along a central axis.

FIG. 7 depicts an orifice hole pattern of a distributor tube.

FIG. 8 depicts a cross-section schematic side view of a point source taken along a central axis.

FIG. 9 depicts a cross-section view along line 9-9 of FIG. 2 of point source configuration within an inline vacuum deposition system.

FIG. 10 depicts a schematic of functional layers in a photovoltaic device.

### DETAILED DESCRIPTION OF EXEMPLARY EMBODIMENTS

Embodiments described herein provide improved vacuum deposition system and method for growing semiconductor single crystal epitaxial layers through vertical upward evaporation or sublimation of elemental materials using thermal sources in a high throughput, inline vacuum deposition system. For illustrative purposes, embodiments are described below with reference to a Gallium Arsenide thin film PV device. However, it should be understood that the embodiments may apply to PV devices other than GaAs thin film PV devices.

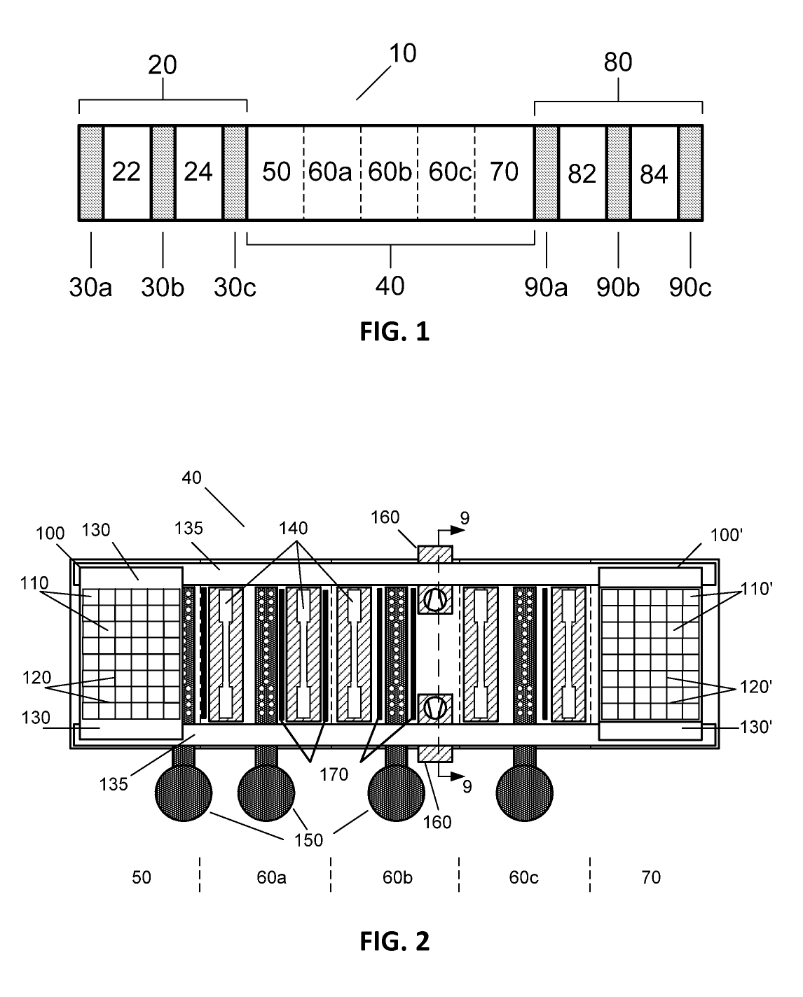

Now referring to the accompanying figures, wherein like reference numbers denote like features, FIG. 1 illustrates a block diagram of the inline vacuum deposition system 10. The system 10 defines an enclosed environment that can be controlled to induce material growth on substrates within the system 10. Within the system 10, the temperature, pressure and elemental composition are controlled to preferred parameters for the desired material growth profile. Substrates, a plate-like base upon which the deposited material will grow into layers of crystalline material, are transported through the system 10 using any suitable mechanisms of conveyance, such as rollers, belts, chains or otherwise.

The system 10 includes entry load lock 20 provided at one end of the system 10 to introduce substrates into the controlled environment of the system 10. In the embodiment illustrated in FIG. 1, first and second chambers 22, 24 of the entry load lock 20 are separated and isolated with gate valves 30a, 30b, 30c. A first gate valve 30a separates the first chamber 22 of entry load lock 20 from the ambient environment and can be opened to allow the introduction of the substrates into the first chamber 22. A second gate valve 30b separates the first chamber 22 from the second chamber 24 and can be opened to allow the conveyance of the substrates into the second chamber 24. A third gate valve 30c separates the second chamber 24 of the entry load lock 20 from the growth chamber 40 and can be opened to allow the conveyance of the substrates into the growth chamber 40.

Although the system 10 is depicted as having first and second chambers 22, 24 within the entry load lock 20, other configurations are possible without departing from the scope of this disclosure. For example, a single chamber entry load lock 20 could be used where the full vacuum of the growth chamber 40 is achieved in a single evacuation step. Alternatively, three or more chambers could be used where each chamber achieves a step-wise reduction in pressure from the ambient environment until the growth chamber vacuum is reached.

The growth chamber 40 is the enclosed chamber within which elemental material sources are evaporated into a vapor flux and then condense into thin films on the exposed surface of the substrates. The growth chamber 40 includes insulated walls to isolate the enclosed environment from the external ambient environment. The growth chamber 40 may include certain control mechanisms that pass through the walls to facilitate the operation of the enclosed elements, such as the conveyance mechanism, thermocouple, pressure sensor, and the like.

Entering the growth chamber 40 of the system 10, the substrates begin in a heating zone 50. The heating zone 50 increases the temperature of the substrates to the process temperature suitable for material formation. Reaching the process temperature, the substrates can be transported through multiple layer deposition zones 60a, 60b, 60c, as will be described below. The multiple layer deposition zones 60a, 60b, 60c can sequentially deposit the functional layers to create a photovoltaic device. After growth of the complete photovoltaic device stack, the substrates are transported through a cooling chamber 70 to reduce the temperature of the substrates.

Complementary to the entry load lock 20, the system 10 further includes exit load lock 80 provided at the opposite exit end of the system 10 to extract the substrates from the system 10. In the embodiment illustrated in FIG. 1, first and second chambers 82, 84 of the exit load lock 80 are separated and isolated with gate valves 90a, 90b, 90c. A first gate valve 90a separates the first chamber 82 of exit load lock 80 from the environment of the growth chamber 40 and can be opened to transport the substrates into the first chamber 82. A second gate valve 90b separates the first chamber 82 from the second chamber 84 and can be opened to allow the conveyance of the substrates into the second chamber 84. A third gate valve 90c separates the second chamber 84 of the exit load lock 80 from the ambient environment and can be opened to allow the extraction of the substrates from the system.

Although the system 10 is depicted in FIG. 2 as having first and second chambers 82, 84 within the exit load lock 80, other configurations are possible without departing from the scope of this disclosure. For example, a single chamber exit load lock 80 could be used where the full vacuum of the growth chamber 40 is brought to atmospheric pressure in a single chamber. Alternatively, three or more chambers could be used where each chamber achieves a step-wise increase in pressure until atmospheric pressure is reached.

Referring now to FIG. 2, a plan view of the growth chamber 40 of the inline vacuum deposition system 10 is illustrated. A wafer platen 100 is shown within the growth chamber 40. The wafer platen 100 is a strong, lightweight plate structure that does not soften or bow when heated, is inert to the process chemistry and supports the substrates as they are transported through the system 10. The wafer platen 100 may be made from any suitable material, for example Carbon Fiber Composites (CFCs), sintered graphite, molybdenum plate, or pyrolytic boron nitride plate.

Square substrates are installed into the openings 110 in the wafer platen 100, each of the openings separated by frame components 120 which interface with and support the edges of the substrates. The frame components may include a milled shelf upon which the substrates rest. This shelf may be present on all four sides of the substrate, or may be present on less than all four sides of the substrate. The overlap of the shelf area onto the deposition face of the substrate should be minimized. The wafer platen 100 as depicted transports an array of six substrates by eight substrates, where each substrate opening 110 may be about 150 mm by 150 mm. In alternative configurations, the wafer platen 100 may transport more or fewer substrates, for example, each wafer platen 100 may transport an array of eight substrates by eight substrates or six substrates by ten substrates, based on the number of substrate openings 110 in the platen and dimensional considerations. Additionally, the substrate openings may be larger or smaller based on the desired size of substrates to be processed through the system 10. High packing density is achieved with square wafers so that more substrate surface area is coated simultaneously as compared with conventional processing methods which use round substrates and round wafer platens.

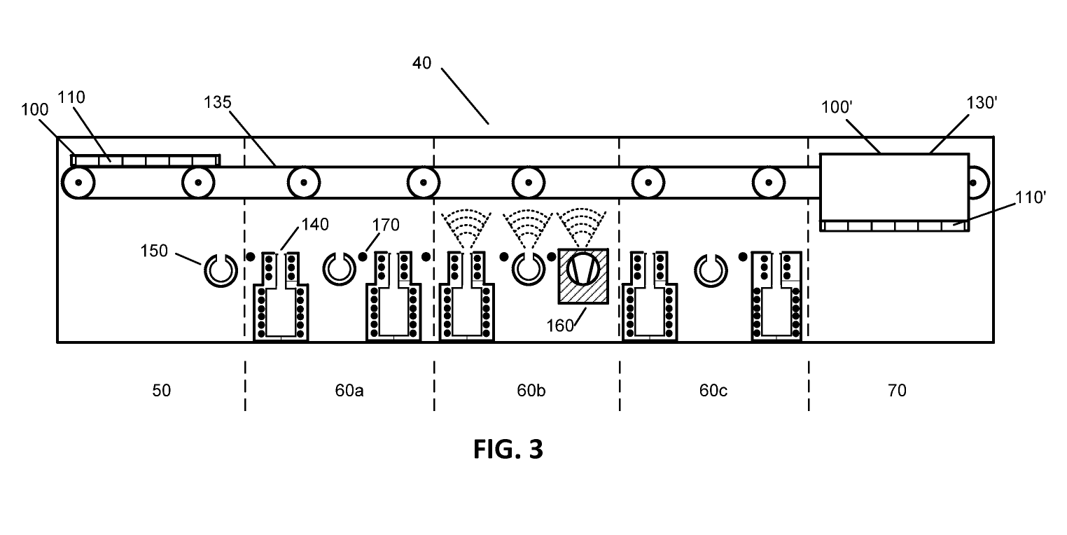

The wafer platens 100 are transported through the growth chamber 40 by a conveyance mechanism 135, which may include rollers, belts, chains or any other suitable conveyance mechanism. The conveyance mechanism 135 further includes a drive mechanism to propel the wafer platen, and thus the substrates, through the growth chamber 40. As shown in FIG. 2, the wafer platen 100 includes side supports 130. The side support 130 of the wafer platen 100 is an area of the platen which interacts with the conveyance mechanism to allow the wafer platen 100 to be transported through the system 10. As shown in FIG. 2, one embodiment of the wafer platen 100 includes a side support 130 along both ends, each side support 130 is a flange to rest atop the conveyance mechanism 135. Alternatively there may be any suitable number of side supports 130 per wafer platen 100, and the side support 130 may include a flange, bracket or other feature suitable to interface with the conveyance mechanism 135. The side supports 130 may be integral with the wafer platen 100 or may be fastened to the wafer platen 100. The side supports 130 may be in a common plane with the substrates, as depicted in FIG. 2. Alternatively, the side supports 130 may be in a plane separate from the substrates to place the substrates away from the plane of the conveyance mechanism 135, as depicted in FIG. 3 wafer platen 100′.

As shown in FIG. 2, the conveyance mechanism 135 supports the wafer platen 100 at the side supports 130 as the wafer platen 100 is moved through the system 10. This engagement may be accomplished, for example, frictionally with rotating rollers or a conveyor belt, or alternatively, the supports 130 may include tooth-like projections (not shown) to engage with a chain-type conveyance. The conveyance mechanism 135 disposed within the system 10 may be continuous though the entry load lock 20, growth chamber 40 and exit load lock 80, or may be discontinuous among the separate chambers. The conveyance mechanism 135 may transport the wafer platen 100 at a continuous and constant speed through the system 10 of between about 0.1 meter per minute and about 1 meter per minute, or alternatively between 0.4 meter per minute and about 0.8 meter per minute, or other suitable speed. Alternatively, the wafer platen 100 may be transported at varying speeds through the system 10, including a step in which the wafer platen 100 dwells at a particular location for a period of time, such as within a load lock chamber or in a heating or cooling chamber.

As shown in FIG. 2 in a top down schematic view, and FIG. 3 in a cross-section side schematic view, the wafer platen 100 is conveyed along the conveyance mechanism 135 above the elemental thermal sources 140, 150, 160. For example, the substrates may be about 40 to 60 cm above the elemental thermal sources 140, 150, 160. The downward facing substrates prevent particulates from adhering to the growth surface from excess material deposition that flakes off the growth chamber's 40 walls.

In one alternative embodiment the conveyance mechanism may be separated from the elemental thermal sources 140, 150, 160 by an increased distance by using a wafer platen 100′ which displaces the side supports 130′ away from the plane of the substrates and substrate openings 110′. This may help reduce material buildup and wear on the conveyance mechanism.

Distributed along the lower portion of the growth chamber 40 are thermal sources which may include linear sources 140, reservoir sources 150, point sources 160, and dopant sources 170, as described in the following paragraphs.

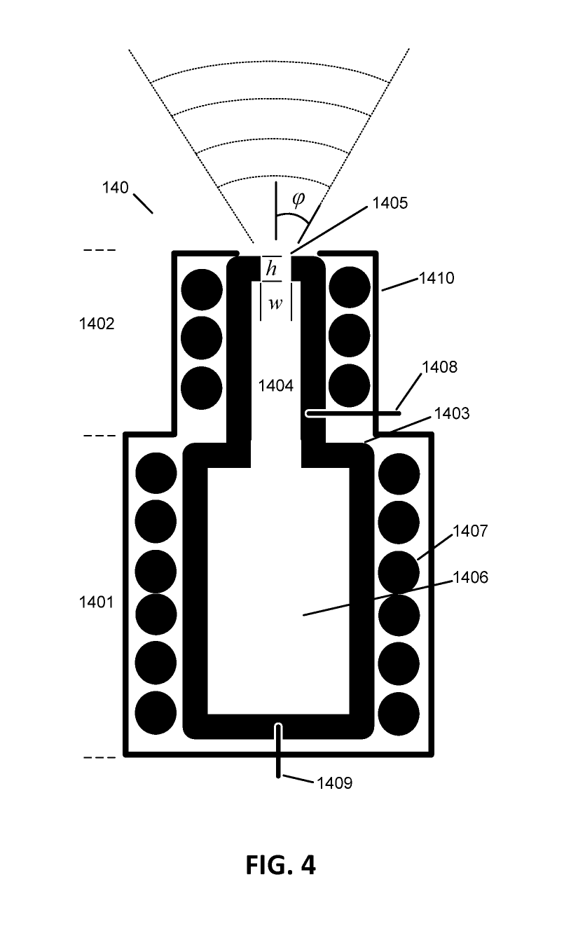

Referring now to FIG. 4, a cross section schematic view of the linear source 140 is depicted. The linear source 140 includes a lower portion 1401 defining a high capacity material reservoir 1406 for a liquid material source and an upper portion 1402 defining a narrower vapor collimator 1404 with a slit-orifice vapor nozzle 1405. The entire body 1403 of the linear source 140 may be formed of dense, high purity graphite; but other suitable materials may be used, such as pyrolytic boron nitride, graphite, titanium, molybdenum or combinations thereof. The lower portion 1401 and upper portion 1402 may be formed integrally, or may be formed as separate components and sealed together using, for example, a flexible graphite foil, flexible alumina foil, or other ceramic material.

The lower portion 1401 and upper portion 1402 are independently heated so that the upper portion 1402 is held at a higher temperature, for example 50° C. or 100° C. higher, than the reservoir to prevent condensation of material on the orifice nozzle 1405. Both the lower portion 1401 and upper portion 1402 may be heated by heater elements 1407. As in the depicted embodiment, the heater rods 1407 include large diameter (e.g. 10 mm) graphite heater rods that are insulated by boron nitride sleeves. In alternative embodiments other heater elements 1407 may be used. Thermocouples 1408, 1409 provided at the vapor collimator 1404 and the reservoir 1406 may measure the temperature of the upper portion 1402 and lower portion 1401 and connect to a control mechanism (not shown) for controlling the heater rods 1407. Surrounding the body 1403 of the linear source 140 and further enclosing the heater rods 1407 adjacent to the body 1403, external heat shields 1410 are provided to insulate the linear source 140 from the surrounding environment and reduce the power required to heat the source.

The width w and the height h of the orifice nozzle 1405 will affect the vapor flux profile of material exiting the orifice nozzle 1405. The flux distribution is generally uniform across the length and away from the ends of the linear source 140. However, the distribution of the flux along the transport direction of the wafer platen 100 varies and can be modeled using a Cos^{N}(φ) dependence. The angle φ is measured with respect to the normal angle to the exit orifices of the sources. The N-factor is determined empirically according to the geometry of the orifices of the sources (orifice height and width) and typically is in the range of N=5-10. Detailed computer modeling of the emitting flux distribution across the wafer platen can be achieved by analysis of the gas flow dynamics in a high vacuum chamber.

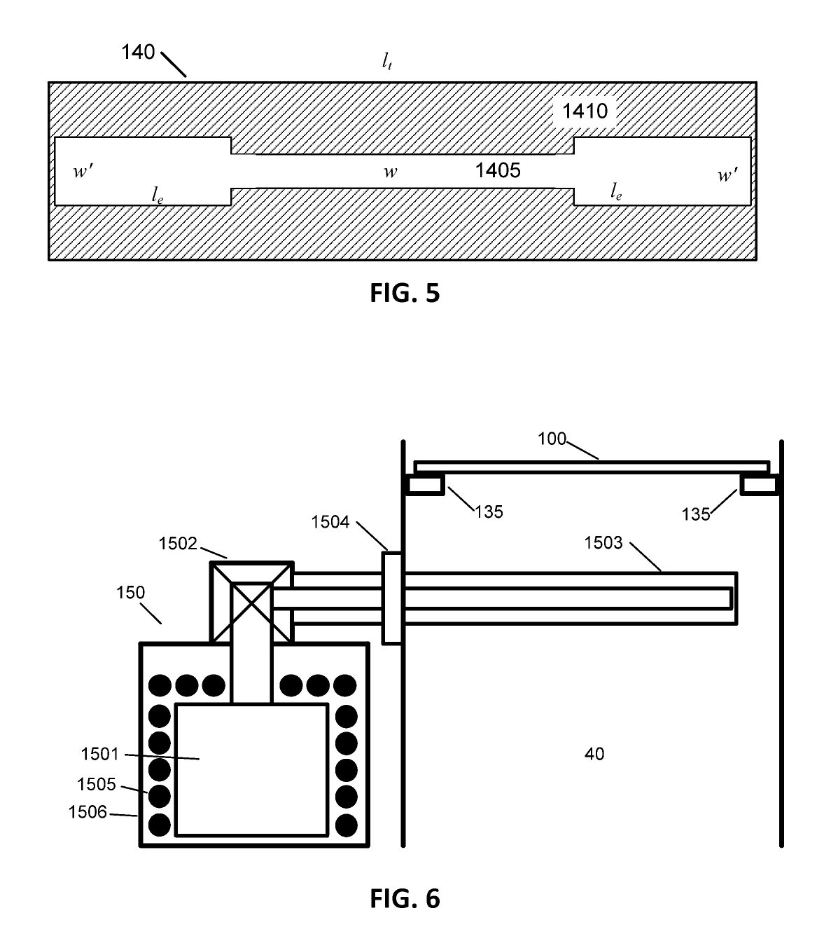

Near the ends of the linear source 140, the vapor flux distribution at the wafer platen 100 may be reduced as vapor flux encounters the wall of the growth chamber 40 adjacent to the end of the linear source 140, and as vapor flux travels upwards around the edge of the wafer platen 100 and away from the substrates. As depicted in FIG. 5, it is desirable to increase the width w′ of the orifice nozzle 1405 at points near the end of the linear source 140 as compared the width w at the middle of the linear source 140. This maintains a more constant vapor flux deposition across the wafer platen 100 for improved thickness uniformity over all of the substrates. The increased end width w′ may be a stepwise increase, as depicted in FIG. 5, present over an end length lₑ at each end of the linear source 140, which is about 5% of the total length lₜ of the orifice nozzle 1405. In alternative configurations, the increased end width w′ may be present over end length lₑ which is about 2%, 8% or up to 15% of the total length lₜ of the orifice nozzle 1405. In further alternative configurations, the increased end width w′ may be present only at the ends of the orifice nozzle 1405 and gradually reduce to central width w as the distance increases from the end.

In alternative embodiments of linear source 140, the total length lₜ may extend beyond the length of the wafer platen 100 across which substrates are installed. This may be a more expensive and less efficient configuration as equipment size is scaled up compared to the substrate surface area being coated, and more vapor flux is distributed into the chamber away from the substrates, resulting in increased deposition on the components of the system 10, such as the wafer platen 100, the conveyance mechanism 135, and the walls of the growth chamber 40.

The deposition rate from a single linear source 140 upon a wafer platen 100 placed statically above the linear source 140 is highly non-uniform. The peak of the normalized flux distribution on the wafer platen 100 is located at the point of the wafer platen 100 directly above the linear source orifice nozzle 1405 and decreases along the surface of the wafer platen 100 as distance increases from the peak point. Uniform material deposition across the surface of the wafer platen 100 may be achieved by evenly spacing multiple linear sources 140 along the growth chamber 40 in the direction of motion of the wafer platen 100 and transporting the wafer platen 100 through the growth chamber 40 at a constant speed, where the linear sources 140 are operated at the same mass flow rate of vapor flux through the orifice nozzle 1405.

Referring now to FIG. 6, a cross section schematic view of the reservoir source 150 is depicted. The reservoir source 150 includes a high capacity reservoir tank 1501 located external of the growth chamber 40. A variable flow valve 1502 is provided in line with the vapor flux communication path between the reservoir 1501 and a distributor tube 1503 to allow the vapor flux distribution rate to be controlled. The valve 1502 may be separately heated to prevent condensation of the material in the vapor flow path. The valve 1502 and a port 1504 in the wall of the growth chamber 40 allow the vapor flux to flow from the reservoir to the enclosed environment within the system 10 for deposition on the substrates on the wafer platen 100. In alternative embodiments, the valve 1502 or the distributor tube 1503 may extend through the wall of the growth chambers 40 to provide a vapor flux communication path. In such case, the wall of the growth chambers 40 interfaces with the valve 1502 or the distributor tube 1503 to isolate the internal environment of the growth chamber 40 from the external atmospheric environment.

The reservoir tank 1501 may be made from titanium, graphite, or other suitable material which is non-reactive with the elemental source material present within the reservoir tank 1501. The reservoir tank 1501 is surrounded by resistance heaters 1505 which heat the reservoir tank and the elemental source material present in the reservoir tank 1501. Heat shields 1506 enclose the reservoir tank 1501 with the resistance heaters 1505 to insulate the reservoir tank 1501 from the surrounding environment and reduce the power required to heat the source.

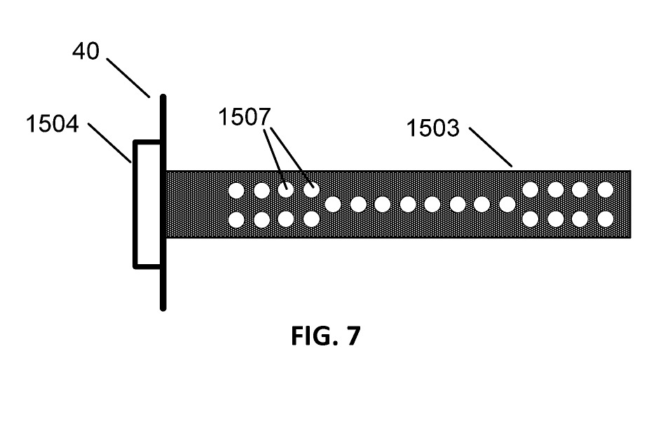

The distributor tube 1503 is separately heated from the reservoir tank 1501, preferably to a temperature higher than the temperature of the reservoir tank 1501, for example 50° C. or 100° C. higher. Alternatively, the distributor tube may be heated to temperatures 200° C. or more higher than the reservoir temperature in order to crack molecular gas species in the vapor stream to lighter weight fragments to enhance material deposition efficiency in the grown films. The distributor tube 1503 is made similarly to the reservoir tank 1501 of titanium, graphite or other non-reactive material. The distributor tube 1503 further includes a pattern of exit orifices 1507 to distribute the vapor flux of the heated elemental source material within the growth chamber 40. An exemplary pattern of exit orifices 1507 is depicted in FIG. 7. It is desirable to provide additional vapor flux distribution at the ends of the reservoir source distributor tube 1503 adjacent to the walls of the growth chamber 40 in order to maintain a more constant material deposition thickness on the substrates present at ends of the wafer platen 100 as compared with the substrates present at the center of the wafer platen 100. This may be achieved by providing more exit orifices 1507 per unit of length along some portion of the distributor tube 1503 proximate to the ends, as shown in FIG. 7. Alternatively, this may be achieved by providing exit orifices 1507 of increased size proximate to the ends of the distributor tube 1503 compared with the size of the exit orifices 1507 present at the center of the distributor tube 1503.

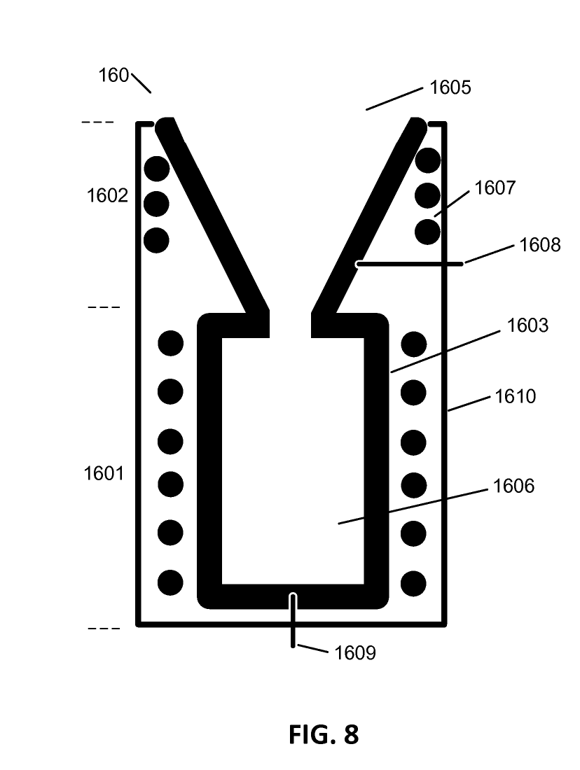

Referring now to FIG. 8, a cross section schematic view of the point source 160 is depicted. The point source 160 includes a lower portion 1601 defining a material reservoir 1606 for a liquid material source and an upper portion 1602 defining a conical vapor nozzle 1605. The entire body 1603 of the point source 160 may be formed of dense, high purity graphite; but other suitable materials may be used, such as pyrolytic boron nitride, molybdenum, titanium, graphite or combinations thereof. The lower portion 1601 and upper portion 1602 may be formed integrally, or may be formed as separate components and sealed together using any suitable mechanism, for example, a flexible graphite foil, flexible alumina foil, or other ceramic materials.

The lower portion 1601 and upper portion 1602 are independently heated so that the upper portion 1602 is held at a higher temperature than the reservoir to prevent condensation of material on the orifice nozzle 1505. Both the lower portion 1601 and upper portion 1602 may be heated by any suitable mechanism, for example cylindrically wound tantalum wire heaters. Alternatively, cylindrically shaped graphite heaters insulated by boron nitride sleeves can be used to heat the reservoir body 1603 and orifice nozzle 1505. Thermocouples 1608, 1609 provided at the conical vapor nozzle 1605 and the reservoir 1606 measure the temperature of the upper portion 1602 and lower portion 1601 and connect to a control mechanism (not shown) for controlling the heater rods 1607. Surrounding the body 1603 of the point source 160 and further enclosing the heater rods 1607 adjacent to the body 1603, external heat shields 1610 are provided to insulate the point source 160 from the surrounding environment and reduce the power required to heat the source.

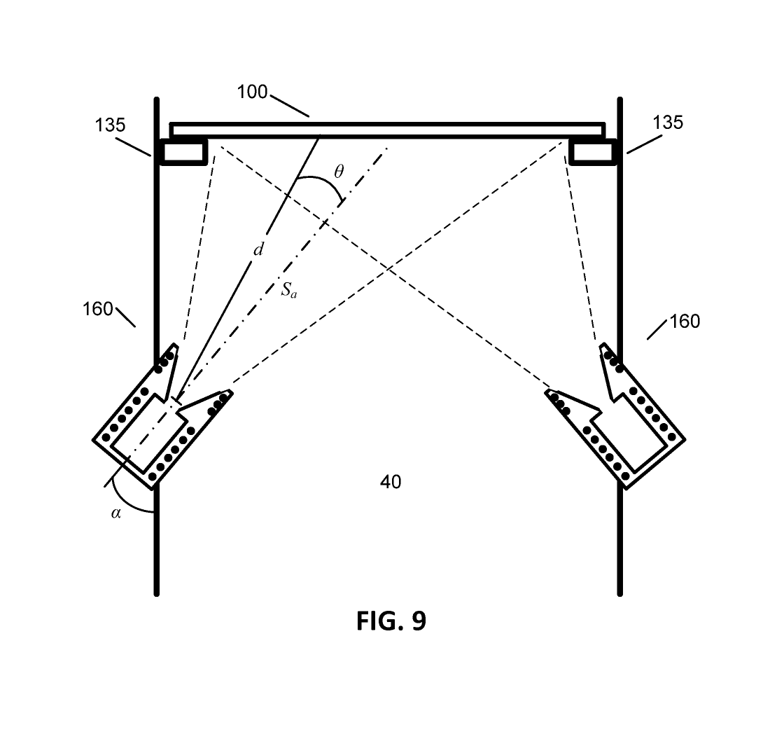

Two point sources 160 may be mounted through opposite sidewalls of the growth chamber 40 of the system 10, as shown in FIGS. 2 and 9. The point sources 160 are inclined upwards at an angle α relative to the vertical direction, determined by the geometry of the point source 160 and the growth chamber 40 so that the total material vapor flux distributed by the oppositely mounted pair of point sources 160 integrate to provide a uniform deposition thickness across the substrates on the moving wafer platen 100. In this configuration, the two point sources 160 behave as independent point sources where the vapor flux has radial symmetry around the source axis Sₐ. The vapor flux incident upon the wafer platen 100 can be approximated by a Cos^{N}(θ)/d² dependence where N is a collimation factor dependent upon geometry of the conical vapor nozzle 1605, θ is the angle from the source to the platen surface measured with respect to the source axis Sₐ, and d is the distance measured from the source nozzle to the platen surface. Computer modeling of the source flux distribution over the wafer platen can be obtained using analysis of the gas flow in high vacuum. The resultant thickness uniformity can be obtained by integration of the static flux distribution over the moving wafer platen.

Both point sources 160 are operated with identical mass flow rates in order to achieve a uniform flux profile across the wafer platen 100. Balancing of the mass flow rates from the point sources 160 can be accomplished using in-situ evaporation rate monitors (not shown) measuring the evaporation rates from the individual point sources 160. Another method to balance the mass flow rates is to measure the deposited film thicknesses at varying distances across the wafer platen by infrared photo-reflectometer (not shown). A computer control algorithm can be implemented to adjust the point source 160 temperatures to achieve the desired material thickness uniformity and deposition rates over the substrates on the wafer platen 100.

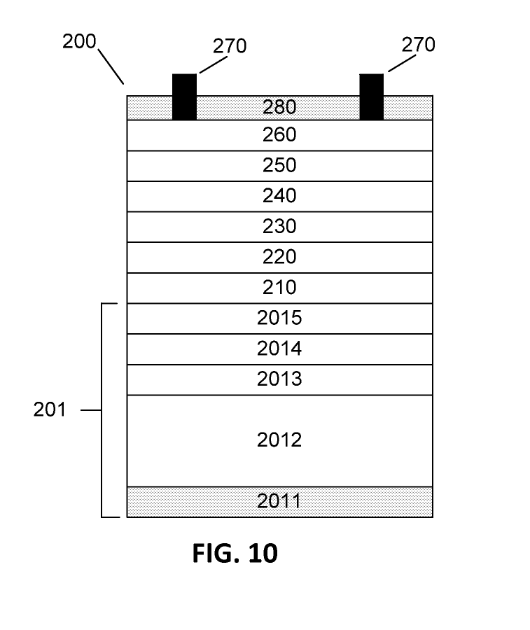

In a particular embodiment, the above described inline vacuum deposition system 10 can be operated to produce a photovoltaic device stack 200, as shown in FIG. 10. The photovoltaic device stack in this embodiment, includes substrate 201, nucleation layer 210, absorber contact layer 220, solar absorber layer 230, emitter layer 240, ohmic contact layer 250, surface passivation layer 260, emitter contact 270, and anti-reflective coating 280.

Dopant sources 170, as shown in FIG. 2, may operate similarly to the preceding described thermal sources 140, 150 and 160, to introduce elemental material into the vacuum environment of the growth chamber 40 of the vacuum deposition system 10. The dopant is a trace impurity element present in the deposited films in order to alter the electrical properties of the deposited films. The particular dopant is selected to provide the desired alteration to the electrical properties. By providing a higher proportion of dopant, a more significant alteration may be achieved. Typical p-type dopants include carbon, for example from Carbon Tetrabromide CBr₄ or Carbon Tetrachloride CCl₄ gaseous sources, or Beryllium as a solid source. Typical n-type dopants include silicon for example from Silicon Tetrachloride (SiCl₄) or Silane (SiH₄) gaseous sources or silicon from a solid source. Alternative n-type dopants include selenium and tellurium from solid sources.

The dopant source 170 may include a distributor tube similar to the distributor tube 1503 depicted in FIG. 7, and may similarly be connected to a reservoir source for evaporating a solid dopant material source or alternatively may be connected to a tank source containing a source gas. In alternative embodiments, solid dopant sources may be evaporated and distributed in linear sources 140 operated at low mass flow rates. In further alternative embodiments, the elemental material sources may be pre-doped and distributed through linear sources 140 and reservoir sources 150 concurrently.

The substrate 201 includes substrate contact layer 2011, a substrate bulk material 2012, strain relief layer 2013 and lattice-matched interface layer 2014. The substrate contact layer 2011 includes a metal foil conductor, or other suitable material, that provides a back contact current pathway through which a charge potential can flow to become an electrical current from the photovoltaic device stack. The substrate bulk material 2012 includes a low-cost single-crystal silicon wafer that is heavily doped for n-type conduction, typically with phosphorus or arsenic. The strain relief layer 2013 minimizes threading dislocations, caused by a mismatch in lattice parameters of adjacent crystalline layers, from propagating into the solar absorber layer 230. A high threading dislocation density, for example, in excess of 1×10⁶ cm⁻² can result in degradation of photovoltaic conversion efficiency due to recombination of electrons and holes. For example, the strain relief layer 2013 can include a thin layer of silicon-germanium alloy, similarly doped for n-type conduction, of Si₍₁₋ₓ₎Geₓ where 0<x<1. The composition of the strain relief layer 2013 may vary through the thickness of the layer so that, for example, adjacent to the substrate bulk material 2012 the alloy has a higher proportion of silicon to germanium and adjacent to the lattice matched interface layer 2014 the alloy has a lower proportion of silicon to germanium. In such instances, the alloy composition of the strain relief layer 2013 can vary continuously through the thickness of the layer, or alternatively, may vary stepwise through a number of sublayers with distinct compositional ratios within the strain relief layer 2013. The lattice-matched interface layer 2014 includes a thin layer of germanium, heavily doped for n-type conduction, typically with phosphorus or arsenic. The lattice-matched interface layer 2014 is provided for fewer surface defects, including threading dislocations, at the interface of the substrate crystallites with the crystallites of the photoactive semiconductor layers deposited by the inline vacuum deposition system 10.

During operation of the vacuum deposition system 10, multiple substrates 201 are loaded into the openings 110 of the wafer platen 100. This may be accomplished manually, through to the use of a robotic handler or by other suitable methods. The loaded wafer platen 100 is introduced into the first chamber 22 of the entry load lock 20 by a robotic handler, manually or through other transportation mechanisms and the first gate valve 30a sealed. The first chamber 22 can then be pumped down from an environment equal to the atmospheric environment external of the system to a rough vacuum, or about 0.1 Torr for about 30 seconds. The second gate valve 30b can then be opened to the second chamber 24 at a similar pressure and the wafer platen 100 transferred from the first chamber 22 to the second chamber 24. The second gate valve 30b sealing the wafer platen 100 into the second chamber 24, the second chamber 24 can then be further evacuated down to high vacuum, or about 0.00001 Torr, at which time the third gate valve 30c is opened and the wafer platen 100 transferred into the growth chamber 40.

The wafer platen 100 is heated to a process temperature of between 550° C. and 600° C. in the heating zone 50 of the growth chamber 40. The process temperature is chosen to be sufficient to thermally desorb the native oxide off of the lattice matched interface layer 2014 of the substrate 201. The wafer platens 100 may be heated to the process temperature using infrared filament heaters, quartz lamps, or other suitable heating means positioned above the wafer platen 100 in the heating zone 50.

In order to form uniform layer compositions and to yield a constant deposition rate as the wafer platen 100 is conveyed through a deposition zone, a source of gallium, either a linear source 140 or a pair of point sources 160, will be matched with a source of arsenic, a reservoir source 150 to create a GaAs source pair. Each GaAs source pair has a dopant source 170 associated with it to selectively adjust the electrical characteristics of the deposited film formed by the GaAs source pair. A number of GaAs source pairs are configured along the length of the growth chamber 40. For example, 10 GaAs source pairs may be configured within the deposition zone 60a, 60b, 60c along the growth chamber 40 length of about 5 meters. Alternatively, the growth chamber 40 length may be about 4 meters, about 6 meters, about 8 meters, or other suitable length. As described above, in a deposition zone where the the desired layer thickness is greater, more GaAs source pairs may be configured to deposit similarly doped material, resulting in a thicker uniform material layer.

As the wafer platen 100 is transported through the growth chamber 40 above the thermal sources the gaseous vapor flux collects on the surface of the substrate as a solid crystal material over time. The speed at which this happens gives a deposition rate of the change in thickness per unit of time. An exemplary process according to the disclosed embodiments may have a deposition rate of between about 6 micrometers per hour and about 12 micrometers per hour. The maximum deposition rate is dependent on the number of thermal sources and the mass flow rate of those sources in the growth chamber 40 and the speed at which the wafer platen 100 passes through the growth chamber 40.

The deposition rate may be limited by the pressure within the growth chamber 40 of the system 10. Each thermal source introducing vapor flux into the growth chamber 40 environment increases the chamber pressure. Additionally, back scattering of material bounding off from the surface of the substrate may increase the chamber pressure. At higher pressures, the molecules within the vapor flux may become scattered leading to non-uniform layer deposition and low quality crystalline structures having a high defect density. Therefore, it is desirable to configure the parameters of chamber pressure, thermal source locations and mass flow rates, conveyance speed, and distance between thermal sources and substrates in a manner so that high quality, uniform thickness layer formation is achieved.

In the first layer deposition zone 60a, an alternating series of linear sources 140 containing gallium, reservoir sources 150 containing arsenic and dopant sources 170 containing a n-type dopant are provided to form n-doped layers of GaAs. In an alternative embodiment the linear sources 140 may be substituted with a pair of oppositely mounted point sources 160 containing gallium. Within the first layer deposition zone 60a a thin nucleation layer 210, typically 0.1 micron or less, of heavily n-doped GaAs is formed as a basis on which the later GaAs bulk crystallites will form. A thin absorber contact layer 220 of n-doped GaAs, typically 0.1-0.3 micron thick, is deposited to provide a low resistance back contact to the underlying lattice matched interface layer 2014 of the substrate 201. A less heavily n-doped GaAs solar absorber layer 230 is then deposited to a thickness between 1.0 to 1.5 microns. The amount of doping may be controlled by increasing or decreasing the amount of dopant material present in the layer deposition zone, for example, by providing more or fewer dopant sources or operating the dopant sources at higher or lower mass flow rates.

In the second layer deposition zone 60b, an emitter layer 240 of p-type GaAs is deposited to a thickness of about 0.20 microns to about 0.30 microns, or of about 0.25 microns. The emitter layer 240 forms a p-n junction with the solar absorber layer 230 to create the electric field that causes the photo-generated free electrons to flow as electrical current in the photovoltaic device stack 200. An ohmic contact layer 250 of heavily p-doped gallium arsenide is then deposited over the solar emitter layer 240.

In the third layer deposition zone 60c, an optional surface passivation layer 260 may be deposited on the layer stack in order to reduce the recombination of the free electrons conducting within the device stack. The surface passivation layer 260 can include p-doped aluminum gallium arsenide or a lattice matched p-doped indium gallium arsenide up to about 0.03 microns thick.

Within each of the layer deposition zones 60a, 60b, and 60c, the linear sources 140, reservoir sources 150, point sources 160, and dopant sources 170 are configured to facilitate the desired material to be grown to the desired thickness. For transporting the wafer platen 100 through the growth chamber 40 at a constant speed, material sources may be placed closer together or may operate at a higher mass flow rate in order to deposit a layer of higher thickness. Conversely, material sources may be spread further apart within a layer deposition zone or may operate at a lower mass flow rate in order to deposit a thinner layer as the wafer platen 100 is transported at a constant speed. In an alternative embodiment, material sources may be distributed evenly throughout a layer deposition zone and operate at a constant mass flow rate with the wafer platen 100 transported at varying speeds to achieve layers of differing thickness. For example, the wafer platen 100 may be transported faster through a layer deposition zone to deposit a thin layer and may be transported slower through to deposit a thicker layer.

After growth of the complete solar cell device stack, the wafer platen 100 moves through a cooling chamber 70 where the wafer platens 100 and the substrates present on the wafer platens 100 are cooled to a temperature of about 300° C. Once substrates have been introduced into the first chamber 82 of the exit load lock 80 and the first gate valve 90a has been sealed, the first chamber 82 can be pumped up from the growth chamber 40 vacuum to the a rough vacuum. The second gate valve 90b can then be opened to the second chamber 84 at a similar pressure and the substrates transferred from the first chamber 82 to the second chamber 84. The second gate valve 90b sealing the substrates into the second chamber 84, the second chamber 84 can then be filled with clean dry nitrogen gas, or other non-reactive or inert gas up to atmospheric pressure, at which time the third gate valve 30c is opened and the substrates removed using a second robotic handler, manually, or through other transportation mechanisms.

To complete the photovoltaic device, the device stacks 200 may be integrated into a photovoltaic module where multiple device stacks are electrically connected. An emitter contact 270, including a metal grid, may be assembled in contact with the surface passivation layer 260. The substrate contact 2011 and the emitter contact 270 together forming the front and back contacts of the photovoltaic device stack. An anti-reflection coating 280 consisting of a multiple layer stack of dielectrics with varying indexes of refraction can be added on top of the top emitter surface to maximize the solar light transmission to the solar absorber region to improve cell efficiency.

From the foregoing description, one ordinarily skilled in the art can easily ascertain the essential characteristics of this invention and, without departing from the spirit and scope thereof, can make various changes and modifications to the invention to adapt it to various usages and conditions. Although a number of embodiments have been described, it will be understood that various modifications can be made without departing from the scope of the invention. Also, it should be understood that the appended drawings are not necessarily to scale, presenting a somewhat simplified representation of various features and basic principles of the invention. The invention is not intended to be limited by any portion of the disclosure and is defined only by the appended claims.

What is claimed:

1. A vacuum deposition system comprising:
a growth chamber including a first deposition zone configured to deposit a compound semiconductor material doped with a first dopant in a first layer; and a second deposition zone configured to deposit the compound semiconductor material doped with a second dopant in a second layer.

2. The vacuum deposition system of claim 1 further comprising:
an entry load lock;
the growth chamber including
the first deposition zone including
a first source pair including one source selected from a first linear source containing a first material and a first coordinated pair of point sources containing a first material, and a first reservoir source containing a second material, and
a first dopant source, the first deposition zone configured to deposit the compound semiconductor material in the first layer including the first and second materials and the first dopant; and
a second deposition zone including
a second source pair including one source selected from a second linear source containing the first material and a second coordinated pair of point sources containing the first material, and a second reservoir source containing the second material, and
a second dopant source, the second deposition zone configured to deposit the compound semiconductor material in a second layer including the first and second materials and the second dopant;
a conveyance mechanism within the growth chamber configured to transport a wafer platen; and
an exit load lock.

3. The vacuum deposition system of claim 2, wherein the first and second source pairs include first and second linear sources containing the first material.

4. The vacuum deposition system of claim 2, wherein one of the first and second source pairs includes a linear source containing the first material and the other of the first and second source pairs includes a coordinated pair of point sources containing the first material.

5. The vacuum deposition system of claim 2, wherein the first material is gallium, the second material is arsenic, the first dopant is an n-type dopant, and the second dopant is a p-type dopant.

6. The vacuum deposition system of claim 2, further comprising a third deposition zone having at least a third source pair and a third dopant source, the third deposition zone configured to deposit the compound semiconductor material in a third layer including the first and second materials and the third dopant.

7. The vacuum deposition system of claim 1, wherein the growth chamber is maintained at vacuum pressure within the range of about 0.1 to about 0.00001 Torr.

8. The vacuum deposition system of claim 2, wherein the first and second source pairs and first and second dopant sources are configured to distribute material vapor vertically upwards.

9. The vacuum deposition system of claim 2, wherein the conveyance mechanism is configured to transport the wafer platen above first and second linear sources, first and second reservoir sources and first and second dopant sources.

10. The vacuum deposition system of claim 5, wherein the first, second and third deposition zone include a total of at least 10 source pairs and dopant sources configured through the first second and third deposition zones,

11. A process for manufacturing a photovoltaic structure comprising:
transporting a wafer platen supporting at least one downward-facing substrate through a vacuum deposition growth chamber above a source pair; and
operating the source pair to deposit a compound semiconductor material on the downward-facing substrate surface.

12. The process of claim 11, wherein transporting the wafer platen includes transporting the wafer platen at a contact speed through the vacuum deposition growth chamber.

13. The process of claim 11 wherein operating the source pair includes operating the source pair to deposit an n-type gallium arsenide compound material layer.

14. The process of claim 11 wherein operating the source pair includes operating the source pair to deposit a p-type gallium arsenide compound material layer.

15. The process of claim 11, wherein operating the source pair includes operating the source pair to deposit a compound material layer selected from among p-type aluminum gallium arsenide and p-type indium gallium arsenide.

16. The process of claim 11 wherein the step of transporting a wafer platen includes transporting the wafer platen through a first deposition zone including a first source pair and a second deposition zone including a second source pair and a second dopant source.

17. The process of claim 16 wherein the step of operating the source pair includes operating the first source pair to deposit a compound semiconductor material in a first layer, and operating the second source pair to deposit a compound semiconductor material in a second layer.

18. The process of claim 17 wherein the step of operating the first source pair further includes operating the first source pair to deposit an n-type gallium arsenide layer.

19. The process of claim 17 wherein the step of operating the second source pair further includes operating the second source pair to deposit a p-type gallium arsenide layer.

20. A photovoltaic structure manufactured by the process of claim 11.
